(19) United States
(12) Patent Application Publication
(10) Pub. No.: US 2025/0151593 A1
(43) Pub. Date: May 8, 2025

(54) DISPLAY PANEL

(71) Applicant: HKC CORPORATION LIMITED, SHENZHEN (CN)

(72) Inventors: Zeyao LI, SHENZHEN (CN); Junfeng XIE, SHENZHEN (CN)

(73) Assignee: HKC CORPORATION LIMITED, SHENZHEN (CN)

(21) Appl. No.: 18/940,789

(22) Filed: Nov. 7, 2024

(30) Foreign Application Priority Data
Nov. 7, 2023 (CN) 202311467585.3

(51) Int. Cl. H10K 59/90; H01L 25/16; H10K 59/121; H10K 59/131

(52) U.S. Cl. CPC H10K 59/90; H01L 25/167; H10K 59/121; H10K 59/131

(57) ABSTRACT

A display panel, including light-emitting units, arranged in a matrix and including a first light-emitting unit, a second light-emitting unit, and a third light-emitting unit of different colors; and subpixel driving circuits, in a one-to-one correspondence with and electrically connected to the light-emitting units for providing driving signals to the light-emitting units. Each of the first light-emitting unit and the second light-emitting unit includes an OLED or QLED, and the third light-emitting unit includes a Micro-LED. The display panel further includes a first power supply alignment and a second power supply alignment; the first power supply alignment is electrically connected to the third light-emitting unit for providing a first common voltage to the third light-emitting unit; the second power supply alignment is electrically connected to the first light-emitting unit and the second light-emitting unit for providing a second common voltage to the first light-emitting unit and the second light-emitting unit.

### CROSS REFERENCE

The present disclosure claims priority of Chinese Patent Application No. 202311467585.3, filed on Nov. 7, 2023, the entire contents of which are hereby incorporated by reference in their entirety.

### TECHNICAL FIELD

The present disclosure relates to the field of display technologies, and more specifically to a display panel.

### BACKGROUND

At present, Micro Light Emitting Diode (Micro-LED) display panel has become one of the research hotspots in the field of display technologies. However, this display technology has the problems of low luminous efficiency of red Micro-LED and the difficulty of mass transfer of three-color Micro-LED, which seriously affect the mass production of Micro-LED display panel.

Whereas Organic Light Emitting Diode (OLED) display panel has the problems of low light efficiency, short material life, and fast attenuation for blue light-emitting material. Therefore, in the process of mass production of OLED, the above deficiencies of the blue light-emitting material greatly limit the development of OLED display technology. The combination of Micro-LED and OLED to form a hybrid panel may complement each other's strengths and weaknesses.

However, since Micro-LED devices and OLED devices each have their own optoelectronic characteristics, the problem of display differences may occur when they are driven under the same driving voltage.

### SUMMARY OF THE DISCLOSURE

The present disclosure provides a display panel.

A display panel, including: a plurality of light-emitting units, arranged in a matrix and including a first light-emitting unit, a second light-emitting unit, and a third light-emitting unit of different colors; and a plurality of subpixel driving circuits, in a one-to-one correspondence with and electrically connected to the plurality of light-emitting units for providing driving signals to the plurality of light-emitting units; wherein each of the first light-emitting unit and the second light-emitting unit includes an organic light-emitting diode (OLED) or a quantum dot light-emitting diode (QLED), and the third light-emitting unit includes a micro light-emitting diode (Micro-LED); the display panel further includes a first power supply alignment and a second power supply alignment; the first power supply alignment is electrically connected to the third light-emitting unit for providing a first common voltage to the third light-emitting unit; the second power supply alignment is electrically connected to the first light-emitting unit and the second light-emitting unit for providing a second common voltage to the first light-emitting unit and the second light-emitting unit.

A display panel, including: a substrate; a driving circuit layer, arranged on a side of the substrate and including a plurality of subpixel driving circuits; and a plurality of light-emitting units, arranged in a matrix and in a one-to-one correspondence with and electrically connected to the plurality of subpixel driving circuits; wherein the plurality of light-emitting units includes a first light-emitting unit, a second light-emitting unit, and a third light-emitting unit of different colors; wherein each of the first light-emitting unit and the second light-emitting unit includes an organic light-emitting diode (OLED) or a quantum dot light-emitting diode (QLED), and the third light-emitting unit includes a micro light-emitting diode (Micro-LED); the driving circuit layer further includes a plurality of first power supply alignments, each extending along a column direction; wherein the third light-emitting unit includes a second electrode, and the second electrodes of the third light-emitting units in a same column or a same row are electrically connected to a corresponding first power supply alignment; a fourth electrode of the first light-emitting unit and a fourth electrode of the second light-emitting unit are electrically connected to each other to form a second power supply alignment for providing a second common voltage to the first light-emitting unit and the second light-emitting unit.

### BRIEF DESCRIPTION OF THE DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the those skilled in the art, without any creative labor.

FIG. 1 is a structural schematic view of a display panel according to a first implementation of the present disclosure.

FIG. 2 is a structural schematic view of an arrangement of light-emitting units according to some embodiments of the present disclosure.

FIG. 3 is a structural schematic view of a display panel according to a second implementation of the present disclosure.

FIG. 4 is a structural schematic view of a display panel according to a third implementation of the present disclosure.

FIG. 5 is a cross-sectional structural schematic view of a display panel according to some embodiments of the present disclosure.

FIG. 6 is a schematic diagram of a layout structure of a first power supply alignment according to some embodiments of the present disclosure.

FIG. 7 is a schematic diagram of a layout structure of a data line according to some embodiments of the present disclosure.

### DETAILED DESCRIPTION

The following description, in conjunction with the accompanying drawings of the specification, provides a detailed description of the program of embodiments of the present disclosure.

In the following description, specific details such as particular system structures, interfaces, techniques, and the like are presented for the purpose of illustration and not for limitation, in order to provide a thorough understanding of the present disclosure.

The technical solutions in the embodiments of the present disclosure will be clearly and completely described below in conjunction with the accompanying drawings in the embodiments of the present disclosure, and it is clear that the described embodiments are only a part of the embodiments of the present disclosure, and not all of the embodiments. Based on the embodiments in the present disclosure, all other embodiments obtained by those skilled in the art without creative labor fall within the scope of the present disclosure.

The terms of “first”, “second”, and “third” in the present disclosure are intended for descriptive purposes only, and are not to be construed as indicating or implying relative importance or implicitly specifying the number of technical features indicated. Thus, a feature defined with “first”, “second”, “third” may include at least one such feature, either explicitly or implicitly. In the description of the present disclosure, “plurality” means at least two, e.g., two, three, etc., unless otherwise expressly and specifically limited. All directional indications (e.g., up, down, left, right, forward, backward . . . ) in the embodiments of the present disclosure are only intended to explain the relative positional relationship, movement, etc. between components in a particular attitude (as shown in the accompanying drawings), and the directional indications are changed accordingly if the particular attitude is changed. Furthermore, the terms “including” and “having” and any variations thereof are intended to cover non-exclusive inclusion. For example, a process, method, system, product or apparatus comprising a series of steps or units is not limited to the listed steps or units, but optionally further includes steps or units that are not listed, or optionally includes other steps or units that are inherent to the process, method, product or apparatus.

Reference to “embodiments” herein means that particular features, structures, or characteristics described in conjunction with the embodiments may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

The present disclosure is described in detail below in connection with the accompanying drawings and embodiments.

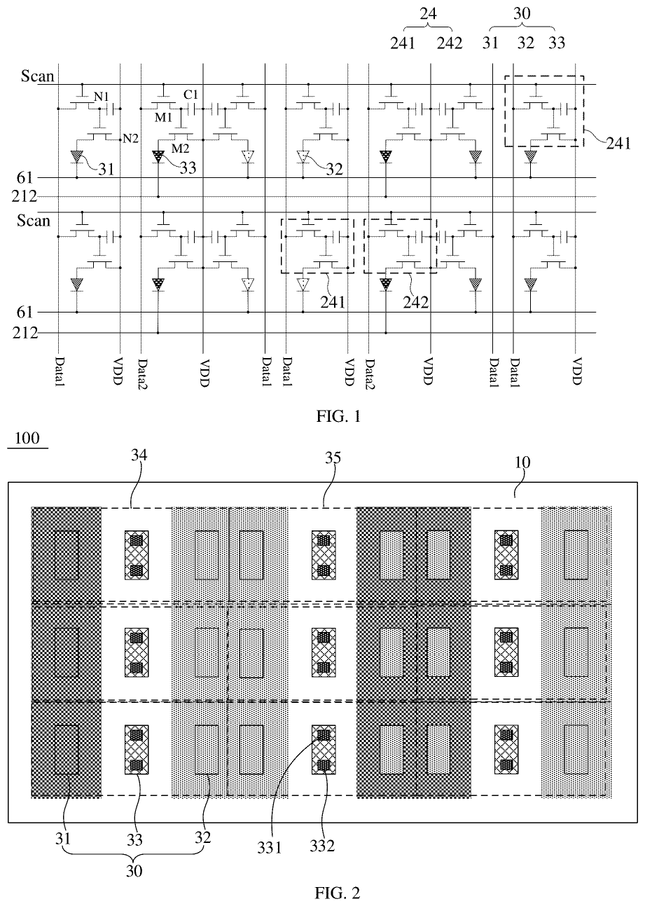

Referring to FIG. 1, FIG. 1 is a structural schematic view of a display panel according to a first implementation of the present disclosure. In the present embodiments, a display panel 100 is provided that includes multiple light-emitting units 30 and multiple subpixel driving circuits 24.

The multiple light-emitting units 30 are arranged in a matrix, and the light-emitting units 30 include a first light-emitting unit 31, a second light-emitting unit 32, and a third light-emitting unit 33 of different colors for realizing a full-color display. Specifically, the first light-emitting unit 31, the second light-emitting unit 32, and the third light-emitting unit 33 may be a red light-emitting unit, a green light-emitting unit, and a blue light-emitting unit, respectively, to emit red light, green light, and blue light, respectively.

The multiple subpixel driving circuits 24 are in a one-to-one correspondence with and electrically connected to the light-emitting units 30 for providing driving signals to the light-emitting units 30. Specifically, each subpixel driving circuit 24 includes a switching unit, a driving unit, and a storage unit; a control end of the switching unit is connected to a scanning line Scan, a first end of the switching unit is connected to a data line, and a second end of the switching unit is connected to a first node N1; a control end of the driving unit is connected to the first node N1, a first end of the driving unit is connected to a second node N2, a second end of the driving unit is connected to an anode of a corresponding light-emitting unit 30, and the second node N2 is connected to a third power supply signal line; a first end of the storage unit is connected to the first node N1, and a second end of the storage unit is connected to the second node N2; a cathode of the corresponding light-emitting unit 30 is connected to a first power supply signal line or a second power supply signal line.

The switching unit includes a switching transistor M1, the driving unit includes a driving transistor M2, and the storage unit includes a storage capacitor C1. A gate of the switching transistor M1 is connected to the scanning line Scan, the first end of the switching transistor M1 is connected to the data line, and the second end of the switching transistor M1 is connected to the first node N1; a gate of the driving transistor M2 is connected to the first node N1, the first end of the driving transistor M2 is connected to the second node N2, and the second end of the driving transistor M2 is connected to the light-emitting element; the first end and the second end of the storage capacitor C1 are connected to the first node N1 and the second node N2, respectively. In the embodiments, the display panel 100 is illustrated with a common 2T1C driving circuit as the subpixel driving circuit 24 as an example, and in other embodiments, the subpixel driving circuit 24 may be other pixel driving circuits with a more complex structure and a more comprehensive function for driving the light-emitting unit 30 to display.

In the embodiments, each of the first light-emitting unit 31 and the second light-emitting unit 32 includes an organic light-emitting diode (OLED) or a quantum dot light-emitting diode (QLED). For example, the first light-emitting unit 31 and the second light-emitting unit 32 may all be OLEDs, or all QLEDs, or may be partly OLEDs and partly QLEDs, as may be set according to actual needs. The third light-emitting unit 33 is a micro light-emitting diode (Micro-LED), and the third light-emitting unit 33 is a blue light-emitting unit, which may complement the advantages of the OLED light-emitting unit 30 and the Micro-LED light-emitting unit 30 and avoid the shortcomings thereof, thereby effectively improving the light-emitting efficiency, service life, and production cost, etc. of the display panel 100.

Specifically, the display panel 100 further includes multiple scan lines Scan and multiple data lines. The scanning line Scan is arranged between two adjacent rows of light-emitting units 30 and extends along a row direction of the matrix for providing a scanning signal to the subpixel driving circuit 24 of the corresponding row. Specifically, the scanning line Scan is electrically connected to the first end of the switching transistor M1 in the subpixel driving circuit 24 of the corresponding row, for controlling the switching transistor M1 to be turned on or off.

The data line is arranged between two adjacent columns of the light-emitting units 30 and extends along a column direction of the matrix for providing a data signal to the subpixel driving circuit 24 of the corresponding column. The data lines include a first data line Data1 and a second data line Data2, and the subpixel driving circuits 24 include a first subpixel driving circuit 241 and a second subpixel driving circuit 242, the first subpixel driving circuit 241 being configured to drive the first light-emitting unit 31 and the second light-emitting unit 32, and the second subpixel driving circuit 242 being configured to drive the third light-emitting unit 33. In the first subpixel driving circuit 241, the first end of the switching transistor M1 is connected to the first data line Data1; and in the second subpixel driving circuit 242, the first end of the switching transistor M1 is connected to the second data line Data2.

Further, in the embodiments, the display panel 100 further includes a first power supply alignment 212 and a second power supply alignment 61; the first power supply alignment 212 is electrically connected to the third light-emitting unit 33 for providing a first common voltage VSS1 to the third light-emitting unit 33; the second power supply alignment 61 is electrically connected to the first light-emitting unit 31 and the second light-emitting unit 32 for providing a second common voltage VSS2 to the first light-emitting unit 31 and the second light-emitting unit 32. That is, in the embodiments, by setting the second power supply alignment 61 to provide the second common voltage VSS2 to the first light-emitting unit 31 and the second light-emitting unit 32, and by setting the first power supply alignment 212 to provide the first common voltage VSS1 to the third light-emitting unit 33, independent driving of the OLEDs and the Micro-LEDs is realized, thereby avoiding display differences between the OLED and the Micro-LED under the same drive and thus improving the display uniformity of the display panel 100.

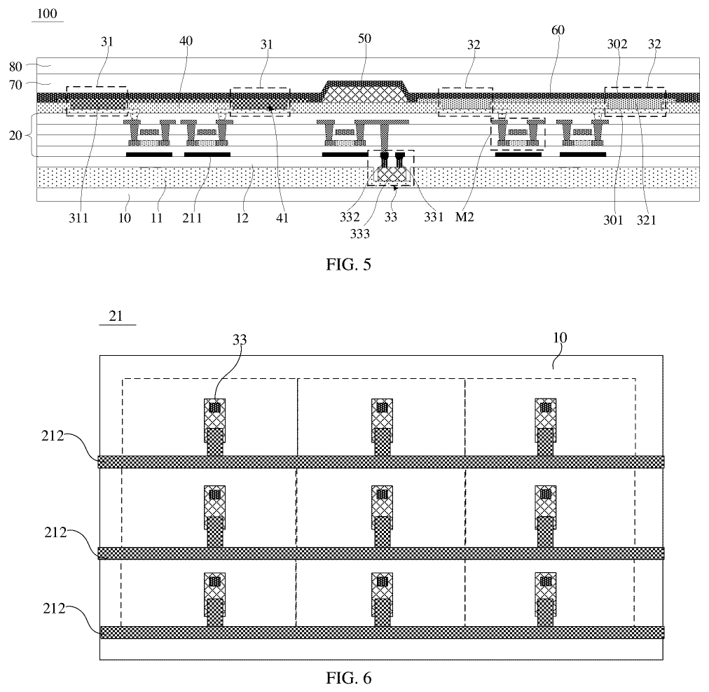

Specifically, the third light-emitting unit 33 includes a first electrode 331 and a second electrode 332; one of the first electrode 331 and the second electrode 332 is an anode, and the other of the first electrode 331 and the second electrode 332 is a cathode. In the present embodiments, the first electrode 331 is an anode and the second electrode 332 is a cathode as an example for illustration. The first light-emitting unit 31 includes a third electrode 301 and a fourth electrode 302 (referring to FIG. 5); one of the third electrode 301 and the fourth electrode 302 is an anode, and the other of the third electrode 301 and the fourth electrode 302 is a cathode. In the present embodiments, the third electrode 301 is an anode and the fourth electrode 302 is a cathode as an example for illustration. The second light-emitting unit 32 is of the same structure as the first light-emitting unit 31, including the third electrode 301 and the fourth electrode 302, and is illustrated in the present embodiments with the third electrode 301 as an anode and the fourth electrode 302 as a cathode.

Specifically, the first power supply alignment 212 is electrically connected to the second electrode 332 of the third light-emitting unit 33 for providing a first common voltage VSS1 to the third light-emitting unit 33, and the second power supply alignment 61 is electrically connected to the fourth electrode 302 of the first light-emitting unit 31 and the fourth electrode 302 of the second light-emitting unit 32 for providing a second common voltage VSS2 to the first light-emitting unit 31 and the second light-emitting unit 32. It is easily understood that the first common voltage VSS1 provided by the first power supply alignment 212 is a low voltage, and the second common voltage VSS2 provided by the second power supply alignment 61 is also a low voltage; the first common voltage VSS1 and the second common voltage VSS2 can be independently commissioned separately because they are provided by the first power supply alignment 212 and the second power supply alignment 61, respectively, such that the driving voltages of the first light-emitting element and the second light-emitting element and the driving voltage of the third light-emitting element can be controlled and debugged separately and independently, thereby avoiding the differences in display caused by the uniform driving due to different types of light-emitting elements and differences in the photoelectric characteristics of the light-emitting elements.

Referring to FIG. 2, FIG. 2 is a structural schematic view of an arrangement of light-emitting units according to some embodiments of the present disclosure. In the present embodiments, a plurality of the first light-emitting units 31, the second light-emitting units 32, and the third light-emitting units 33 form multiple repeating units. Specifically, the repeating units include a first repeating unit 34 and a second repeating unit 35. In the first repeating unit 34, the first light-emitting unit 31 is disposed in a first direction of the third light-emitting unit 33, and the second light-emitting unit 32 is disposed in a direction opposite to the first direction of the third light-emitting unit 33. In the second repeating unit 35, the second light-emitting unit 32 is disposed in the first direction of the third light-emitting unit 33, and the first light-emitting unit 31 is disposed in a direction opposite to the first direction of the third light-emitting unit 33. It can be understood that a first light-emitting unit 31, a second light-emitting unit 32, and a third light-emitting unit 33 form a repeating unit. In the first repeating unit 34, the first light-emitting unit 31, the second light-emitting unit 32, and the third light-emitting unit 33 are arranged in the manner of “R-B-G”, with R representing the first light-emitting unit 31, B representing the third light-emitting unit 33, and G representing the second light-emitting unit 32. Whereas in the second repeating unit 35, the first light-emitting unit 31, the second light-emitting unit 32, and the third light-emitting unit 33 are arranged in the manner of “G-B-R”. That is, in each repeating unit, the first light-emitting unit 31 and the second light-emitting unit 32 are disposed on opposite sides of the third light-emitting unit 33; for example, in the first repeating unit 34, the first light-emitting unit 31 is disposed on the left side of the third light-emitting unit 33 and the second light-emitting unit 32 is disposed on the right side of the third light-emitting unit 33; in the second repeating unit 35, the first light-emitting unit 31 is disposed on the right side of the third light-emitting unit 33, and the second light-emitting unit 32 is disposed on the left side of the third light-emitting unit 33.

In addition, the repeating units are arranged in a matrix, with the first repeating unit 34 and the second repeating unit 35 being arranged alternately in any row or any column. That is, in the same row, the first repeating unit 34 and the second repeating unit 35 are arranged alternately, and in the same column, the same kind of repeating unit (i.e., the first repeating unit 34 or the second repeating unit 35) are arranged; in this way, in the row direction, each two adjacent first light-emitting units 31 have no light-emitting unit arranged therebetween, and each two adjacent second light-emitting units 32 have no light-emitting unit arranged therebetween; and in the column direction, the light-emitting units 30 in the same column are always of the same color. Alternatively, in the same column, the first repeating unit 34 and the second repeating unit 35 are arranged alternately, and in the same row, the same kind of repeating unit (i.e., the first repeating unit 34 or the second repeating unit 35) are arranged; in this way, in the column direction, each two adjacent first light-emitting units 31 have no light-emitting unit arranged therebetween, and each two adjacent second light-emitting units 32 have no light-emitting unit arranged therebetween; and in the row direction, the light-emitting units 30 in the same column are always of the same color. In the embodiments of the present disclosure, the first repeating unit and the second repeating units are arranged alternately in any row, and the same kind of light-emitting units 30 are arranged in any column as an example for illustration.

The first data line Data1 extends in the column direction, and the first data line Data1 is electrically connected to the subpixel driving circuits 24 electrically connected to the first light-emitting units 31 and/or the second light-emitting units 32 in the same column. That is, each first subpixel driving circuit 241 in the same column is electrically connected to the same first data line Data1. Specifically, the arrangement of the light-emitting units 30 in the present embodiments is as shown in FIG. 2, such that the light-emitting units 30 in the same column are of the same color, i.e., the first light-emitting units 31 or the second light-emitting units 32 or the third light-emitting units 33 are arranged in the same column; the first light-emitting units 31 in the same column are electrically connected to the same first data line Data1 through corresponding subpixel driving circuits 24, and the second light-emitting units 32 in the same column are electrically connected to another same first data line Data1 through corresponding subpixel driving circuits 24; specifically, the first data line Data1 is electrically connected to the first end of the switching unit of the first subpixel driving circuit 241 for providing a corresponding data signal when the switching unit is turned on.

The second data line Data2 extends in the column direction, and the second data line Data2 is electrically connected to the subpixel driving circuits 24 electrically connected to the third light-emitting unit 33 in the same column. That is, each second subpixel driving circuit 242 in the same column is electrically connected to the same second data line Data2. Specifically, the second data line Data2 is electrically connected to the first end of the switching unit of the second subpixel driving circuit 242 for providing a corresponding data signal after the switching unit is turned on.

Referring to FIG. 1, in the embodiments, the display panel 100 further includes a third power supply alignment VDD extending along the column direction; the third power supply alignment VDD is electrically connected to each subpixel driving circuit 24 of the corresponding column for providing a power supply voltage to the subpixel driving circuit 24; multiple the third power supply alignments VDD are shorted through a third power supply bus located at an edge of the display panel 100. Specifically, the third power supply alignment VDD is electrically connected to the second node N2 in the subpixel driving circuit 24 of the corresponding column for providing a power supply voltage to the driving unit, so as to provide a driving current to the light-emitting unit 30 when the driving unit is turned on, thereby driving the light-emitting unit 30 to emit light.

In the embodiments, each column of the second subpixel driving circuits 242 shares the same third power supply alignment VDD with an adjacent column of first subpixel driving circuits 241. Specifically, the structure of each column of the second subpixel driving circuits 242 may be symmetrically set up with the structure of an adjacent column of the first subpixel driving circuits 241, such that the second node N2 in the two columns of subpixel driving circuits 24 are adjacent to each other. In this way, the third power supply alignment VDD can be arranged between the two columns of subpixel driving circuits 24, and all the second nodes N2 of the two columns of subpixel driving circuits 24 can be connected to the third power supply alignment VDD. Through the above-described setup, it is possible to reduce the number of the third power supply alignment VDDs, thereby simplifying the layout of the alignments of the third power supply alignment VDDs, and preventing the response rate of the subpixel driving circuit 24 and the accuracy of the driving voltage from being affected due to the fact that too many third power supply alignment VDDs are prone to generate parasitic capacitance with other signal alignments, so as to ensure the display effect of the display panel.

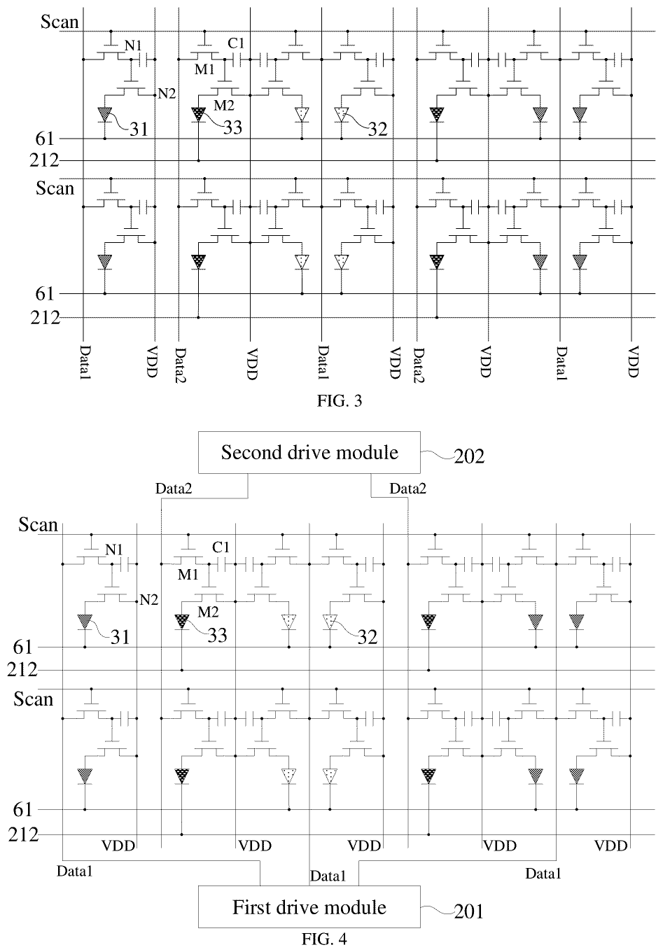

Referring to FIG. 3, FIG. 3 is a structural schematic view of a display panel according to a second implementation of the present disclosure. In the present embodiments, the light-emitting units 30 are arranged in the same manner as the light-emitting units 30 in the embodiments of FIG. 2. Further, the first subpixel driving circuits 241 of the two adjacent columns of the first light-emitting unit 31 share the same first data line Data1, and/or the first subpixel driving circuits 241 of the two adjacent columns of the second light-emitting unit 32 share the same first data line Data1. That is, two adjacent columns of the subpixel driving circuits 24 electrically connected to the first light-emitting units 31 are electrically connected to the same first data line Data1; and/or, two adjacent columns of the subpixel driving circuits 24 electrically connected to the second light-emitting units 32 are electrically connected to the same first data line Data1.

By making the two adjacent columns of OLED/QLED light-emitting units 30 share the same first data line Data1, it is possible to effectively reduce the number of data channels of the OLED/QLED light-emitting units 30, such that the number of data channels of the OLED/QLED light-emitting units 30 is the same as the number of data channels of the Micro-LED light-emitting units 30. Further, it is possible to effectively reduce the number of data lines in order to simplify the alignment layout of the display panel 100 and the capacity of the data information.

For the display panel 100 provided by the embodiments of the present disclosure, the power line spanning voltage of the OLED/QLED light-emitting unit 30 is VDD-VSS2, and the power line spanning voltage of the Micro-LED light-emitting unit 30 is VDD-VSS1. That is, by providing the cathode of the two types of light-emitting units 30 with separate common voltages, it is possible to realize separate debugging of the two types of light-emitting units 30 with separate spanning voltages, thereby overcoming the difference in optoelectronic characteristics between the OLED and the Micro-LED, reducing the difference in brightness between the OLED/QLED light-emitting unit 30 and the Micro-LED light-emitting unit 30, and thus improving the uniformity of the brightness of the display panel 100.

Referring to FIG. 4, FIG. 4 is a structural schematic view of a display panel according to a third implementation of the present disclosure. In the present embodiments, the display panel 100 further includes a first drive module 201 and a second drive module 202. The first drive module 201 is electrically connected to the first data line Data1 for providing a data signal to the first light-emitting unit 31 and the second light-emitting unit 32, i.e., for providing the data signal to the first subpixel driving circuits 241. The second drive module 202 is electrically connected to the second data line Data2 for providing a data signal to the third light-emitting unit 33, i.e., for providing the data signal to the second subpixel driving circuit 242.

It is to be understood that the OLED and/or QLED light-emitting units 30 are provided with data signals by the first drive module 201, and the Micro-LED light-emitting units 30 are provided with data signals by the second drive module 202, which further improves the uniformity of the brightness of the display panel 100 by enabling the two different kinds of light-emitting units 30 to be driven by separate drive modules to meet their respective optoelectronic characteristics.

Referring to FIG. 5, FIG. 5 is a cross-sectional structural schematic view of a display panel according to some embodiments of the present disclosure. In the present embodiments, the display panel 100 includes a substrate 10, a driving circuit layer 20, and light-emitting units 30 for displaying an image.

The substrate 10 is configured to carry the driving circuit layer 20 and the light-emitting unit 30. The substrate 10 may specifically be a glass substrate or a flexible substrate, which may be set according to actual needs. The driving circuit layer 20 is arranged on a side of the substrate 10; the driving circuit layer 20 includes multiple subpixel driving circuits 24, and the subpixel driving circuits 24 are electrically connected to the light-emitting units 30 for driving the light-emitting units 30 to emit light. The structure and function of the subpixel driving circuits 24 are the same or similar to those of the subpixel driving circuits 24 involved in the embodiments above, and the same technical effect can be realized, as can be described in detail above, which will not be repeated herein.

Each light-emitting unit 30 is electrically connected to the driving transistor M2 of a corresponding subpixel driving circuit 24 in the driving circuit layer 20. The light-emitting units 30 include a first light-emitting unit 31, a second light-emitting unit 32, and a third light-emitting unit 33 of different colors for realizing a full-color display. Specifically, the first light-emitting unit 31, the second light-emitting unit 32, and the third light-emitting unit 33 may be a red light-emitting unit 30, a green light-emitting unit 30, and a blue light-emitting unit 30, respectively, for emitting red light, green light, and blue light, respectively.

As in the above embodiments, each of the first light-emitting unit 31 and the second light-emitting unit 32 includes an organic light-emitting diode (OLED) or a quantum dot light-emitting diode (QLED). For example, the first light-emitting unit 31 and the second light-emitting unit 32 may be all OLEDs, or all QLEDs, or may be partly OLED and partly QLED, which may be set according to actual needs. The third light-emitting unit 33 is a micro light-emitting diode (Micro-LED). The OLED/QLED light-emitting units 30 and the Micro-LED light-emitting unit 30 are mixed on the display panel 100, which may complement the advantages of the OLED light-emitting unit 30 and the Micro-LED light-emitting unit 30 and avoid the shortcomings thereof, thereby effectively improve the light-emitting efficiency, service life, and production cost of the display panel 100.

In the embodiments, the first light-emitting unit 31 and the second light-emitting unit 32 are disposed on a side of the driving circuit layer 20 away from the substrate 10 and are prepared through an evaporation process; the third light-emitting unit 33 is a micro light-emitting diode (Micro-LED), which does not require an evaporation process and is disposed between the driving circuit layer 20 and the substrate 10. That is, the third light-emitting unit 33 is a Micro-LED and is disposed below the driving circuit layer 20.

Continuing to refer to FIG. 5, the display panel 100 further includes a buffer layer 11 and a first encapsulation layer 12; the buffer layer 11 is disposed between the substrate 10 and the driving circuit layer 20, and multiple accommodation slots are defined on a side of the buffer layer 11 away from the substrate 10 for holding the third light-emitting units 33. Specifically, the buffer layer 11 may be a transparent material such as a transparent photoresist material, and the buffer layer 11 has a thickness in a range of 2 to 15 μm, such that the depth of the accommodation slots can satisfy the accommodation requirements of the third light-emitting units 33. The accommodation slot may be formed by etching through a photolithography process. The third light-emitting units 33 are transferred to the accommodation slots by a mass transfer process, and each third light-emitting unit 33 is arranged in a corresponding accommodation slot, where the first electrode 331 and the second electrode 332 of the third light-emitting unit 33 are oriented toward a slot opening of the corresponding accommodation slot. That is, the third light-emitting unit 33 is inverted in the accommodation slot. An epitaxial layer 333 is oriented toward the substrate 10, and the first electrode 331 and the second electrode 332 are oriented toward the driving circuit layer 20.

The first encapsulation layer 12 is arranged between the buffer layer 11 and the driving circuit layer 20 for encapsulating the third light-emitting unit 33, i.e., the first encapsulation layer 12 is arranged on a side of the buffer layer 11 away from the substrate 10 and covers the third light-emitting unit 33 to encapsulate the third light-emitting unit 33. The first encapsulation layer 12 may likewise be made of a transparent insulating material, such as a transparent photoresist or an inorganic transparent insulating material, and a transparent photoresist material is adopted in the present embodiments; the first encapsulation layer 12 defines multiple openings, the openings being defined corresponding to and facing the first electrode 331 and the second electrode 332 of the third light-emitting unit 33, such that the first electrode 331 and the second electrode 332 are exposed for electrical connection.

The display panel 100 further includes a pixel defining layer 40, a first electrode layer, a light-emitting layer, and a second electrode layer 60. The first electrode layer is arranged on a side of the driving circuit layer 20 away from the substrate 10, and the first electrode layer includes multiple third electrodes 301; each third electrode 301 is electrically connected to the driving transistor M2 in a corresponding subpixel driving circuit 24 of the driving circuit layer 20, and the third electrode 301 may be formed by a patterning process; the third electrode 301 serves as an anode of a corresponding one of the first light-emitting unit 31 and the second light-emitting unit 32. Specifically, the third electrode 301 is misaligned with the third light-emitting unit 33 in a direction perpendicular to the substrate 10, i.e., a positive projection of the third electrode 301 on the substrate 10 does not overlap with a positive projection of the third light-emitting unit 33 on the substrate 10, such that the first light-emitting unit 31, the second light-emitting unit 32, and the third light-emitting unit 33 are completely misaligned in the direction perpendicular to the substrate 10, to avoid mutual occlusion.

The pixel defining layer 40 is arranged on a side of the third electrode 301 away from the substrate 10, and the pixel defining layer 40 may be specifically prepared by a photolithographic process; the pixel defining layer 40 defines multiple pixel openings 41 in a one-to-one correspondence with the third electrodes 301 for exposing the third electrodes 301. That is, the third electrodes 301 are at least partially disposed in the multiple pixel openings 41 to ensure that the contact area between the light-emitting layer and the third electrode 301. Specifically, the pixel defining layer 40 is arranged on the driving circuit layer 20 and covers an edge part of the third electrode 301.

The light-emitting layer is arranged in the pixel opening 41 and covers the third electrode 301, forming an ohmic contact with the third electrode 301. The light-emitting layer includes a first light-emitting layer 311 and a second light-emitting layer 321 of different colors, the first light-emitting layer 311 being configured to emit red light and the second light-emitting layer 321 being configured to emit green light, and each of the first light-emitting layer 311 and the second light-emitting layer 321 being disposed within a corresponding pixel opening 41 in a preset regularity. Specifically, the first light-emitting layer 311 and the second light-emitting layer 321 are formed by two vaporization processes, i.e., the first light-emitting layer 311 is formed by a first vaporization process, and then the second light-emitting layer 321 is formed by a second vaporization process.

The second electrode layer 60 is arranged on a side of the light-emitting layer away from the substrate 10, and the second electrode layer 60 includes multiple fourth electrodes 302 electrically connected to each other; each of the fourth electrodes 302 is arranged within a corresponding pixel opening 41 and cover the light-emitting layer, forming an ohmic contact with the light-emitting layer to act as a cathode of a corresponding one of the first light-emitting unit 31 and the second light-emitting unit 32. The second electrode layer 60 may specifically be formed by a vapor deposition or photolithography process to form the multiple fourth electrodes 302, the fourth electrodes 302 being arranged in a one-to-one correspondence with the first light-emitting layer 311 and the second light-emitting layer 321, and the multiple fourth electrodes 302 being connected to each other to form a faceted structure or a mesh structure. In each pixel opening 41, the third electrode 301, the first light-emitting layer 311, and the fourth electrode 302 form one first light-emitting unit 31; or, the third electrode 301, the second light-emitting layer 321, and the fourth electrode 302 form one second light-emitting unit 32.

It is to be noted that the second electrode layer 60 is provided by arranging the second electrode layer 60 on a side of the light-emitting layer away from the substrate 10, and the multiple fourth electrodes 302 in the second electrode layer 60 are electrically connected to each other to form a faceted structure or a mesh structure to serve as the second power supply alignment 61, for providing the second common voltage VSS2 to the first light-emitting unit 31 and the second light-emitting unit 32.

Referring to FIG. 6, FIG. 6 is a schematic diagram of a layout structure of a first power supply alignment according to some embodiments of the present disclosure. Further, in the present embodiments, the driving circuit layer 20 further includes multiple first power supply alignments 212; the first power supply alignments 212 may be disposed on a first metal layer 21 of the driving circuit layer 20; the first power supply alignment 212 extends in a first direction, and the second electrodes 332 of the third light-emitting units 33 in each row or column are electrically connected to the same first power supply alignment 212 for providing a first common voltage VSS1 to the third light-emitting units 33. In this way, a low voltage is provided to the third light-emitting units 33 by separately setting the first power supply alignment 212, such that the third light-emitting unit 33 is driven separately from the first light-emitting unit 31 and the second light-emitting unit 32. As a result, the driving signal provided by the subpixel driving circuit 24 to the third light-emitting unit 33 is more closely matched to the third light-emitting unit 33, thereby improving the display effect of the display panel 100 and making the imaging reproduction higher. The first direction may be the row direction or the column direction of the matrix. That is, when the first direction is the row direction, the second electrodes 332 of the third light-emitting units 33 of the same row are electrically connected to the same first power supply alignment 212; and when the first direction is the column direction, the second electrodes 332 of the third light-emitting units 33 of the same column are electrically connected to the same first power supply alignment 212. In the present embodiments, the first direction is the row direction of the matrix as an example for illustration.

That is, by arranging the power supply alignment for the cathode of the OLED/QLED light-emitting unit 30 and the power supply alignment for the cathode of the Micro-LED light-emitting unit 30 to be aligned with different layers respectively, and providing the first common voltage VSS1 and the second common voltage VSS2 respectively, the two common voltages can be regulated independently, so as to satisfy the needs of the two types of light-emitting units 30 with different driving voltages.

In this way, the first power supply alignment 212 is arranged in the driving circuit layer 20 and electrically connected to the second electrode 332 of the third light-emitting unit 33 to provide the first common voltage VSS1 to the third light-emitting unit 33; and the second power supply alignment 61 involved in the above embodiments is formed by electrically connecting the fourth electrodes 302 of the second electrode layer 60 with each other to provide the second common voltage VSS2 to the first light-emitting unit 31 and the second light-emitting unit 32, so as to realize separate regulation of the driving voltages of the different light-emitting units 30 and meet the demand for different driving voltages of different light-emitting elements, thereby improving the brightness uniformity of the display panel 100.

In the embodiments, the driving circuit layer 20 includes a first metal layer 21, a first insulating layer, an active layer, a second insulating layer, a second metal layer, a third insulating layer, and a third metal layer disposed in a sequential cascade.

The first power supply alignment 212 is disposed in the first metal layer 21; the first metal layer 21 further includes multiple patterned light shielding layers 211 for shielding light for the active layer, thereby preventing the transistor output characteristics from being shifted caused by the active layer being exposed to light. A positive projection of the active layer on the substrate 10 falls within a positive projection of the light-shielding layer 211 on the substrate 10. The active layer material may specifically include semiconductor materials such as amorphous silicon (a-Si), low-temperature polycrystalline silicon (LTPS), indium gallium zinc oxide (IGZO), and low-temperature polycrystalline oxide (LTPO), which may be selected according to actual needs, and there is no specific limitation thereon.

The second metal layer includes a gate and a scanning line Scan. The scanning line Scan extends along the row direction of the matrix, and the gates of the same row are electrically connected to the same scanning line Scan. The gates herein may be the gates of the switching transistor M1 and the driving transistor M2 in the subpixel driving circuit 24, and the scanning line Scan is electrically connected to the gate of the switching transistor M1.

The third metal layer includes a source, a drain, a third electrode 301, a data line, the third power supply alignment VDD, and the third electrode 301, the third electrode 301 being electrically connected to the source. The source and the drain herein are the source and the drain of the drive transistor M2, where each third electrode 301 serves as the anode of a corresponding one of the first light-emitting unit 31 and the second light-emitting unit 32, and the third electrode 301 is electrically connected to the source of the drive transistor M2.

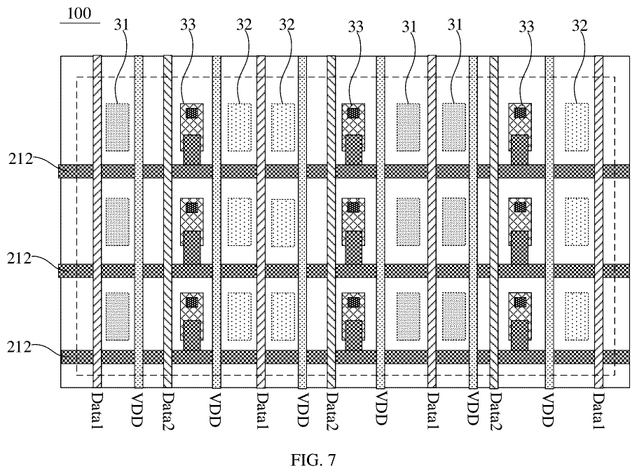

Specifically, the data lines include a first data line Data1 and a second data line Data2, and the connection structure and function of the first data line Data1 and the second data line Data2 are the same as or similar to the connection structure and function of the first data line Data1 and the second data line Data2 involved in the above embodiments, and thus the same technical effect can be realized. The connection structure and function of the third power supply alignment VDD are the same or similar to the connection structure and function of the third power supply alignment VDD involved in the above embodiments, and thus the same technical effect can be realized. The layout of the data lines and the third power supply alignment VDD on the third metal layer is shown in FIG. 7, as described in detail below.

Referring to FIG. 7, FIG. 7 is a schematic diagram of a layout structure of a data line according to some embodiments of the present disclosure. In the present embodiments, each data line is arranged between adjacent light-emitting units 30 and extends along the column direction of the matrix, and is electrically connected to the subpixel driving circuits 24 of the corresponding column; the third power supply alignment VDD is arranged between adjacent light-emitting units 30 and extends along the column direction of the matrix; the third power supply alignment VDD and the data line are spaced alternately in sequence along the row direction; the third power supply alignment VDD is electrically connected to the second node N2 in the subpixel driving circuit 24 for providing a power supply voltage to a corresponding light-emitting unit 30; specifically, the third power supply alignment VDD is electrically connected to the drain of the driving transistor M2 in the subpixel driving circuit 24 for providing a power supply voltage to the corresponding light-emitting unit 30.

In the embodiments, two adjacent columns of the subpixel driving circuits 24 electrically connected to the first light-emitting unit 31 or the second light-emitting unit 32 are electrically connected to the same data line; i.e., by making the two adjacent columns of OLED/QLED light-emitting units 30 share a common first data line, Data1, it is possible to effectively reduce the number of data channels of the OLED/QLED light-emitting units 30, such that the OLED/QLED light-emitting units 30 have the same number of data channels as that of the Micro-LED light-emitting units 30. In this way, the number of data lines can be effectively reduced to simplify the layout of the alignment of the display panel 100 and the capacity of the data information.

In the present embodiments, the first light-emitting unit 31, the second light-emitting unit 32, and the third light-emitting unit 33 are arranged in the same manner as the arrangement of the light-emitting units 30 involved in the above embodiments. In this way, in the same row or in the same column, in a set of a first repeating unit and a second repeating unit adjacent thereto, the first light-emitting unit 31 in the first repeating unit and the first light-emitting unit 31 in the second repeating unit are adjacent to each other, or the second light-emitting unit 32 in the first repeating unit and the second light-emitting unit 32 in the second repeating unit in the first repeating unit are adjacent to each other. Since in the same row and/or in the same column, each two adjacent first light-emitting units 31 have no light-emitting unit arranged therebetween, and each two adjacent second light-emitting units 32 have no light-emitting unit arranged therebetween, the two adjacent first light-emitting units 31 can share the same vaporization opening on the mask plate during the vaporization process, and the two adjacent second light-emitting units 32 can share the same vaporization opening on the mask plate during the vaporization process, thereby enabling the key dimensions of the first light-emitting unit 31 and the second light-emitting unit 32 to be reduced to one-half of the original size, and thus doubling the pixel density of the display panel 100 and effectively improving the pixel resolution.

Returning to FIG. 5, the display panel 100 further includes a support portion 50; the support portion 50 is disposed on a side of the pixel defining layer 40 away from the substrate 10, and a positive projection of the support portion 50 on the substrate 10 is overlapped with a positive projection of the third light-emitting unit 33 on the substrate 10. It can be understood that since the third light-emitting unit 33 is a Micro-LED, which is not required to be made by a vaporization process, and the third light-emitting unit 33 is arranged below the driving circuit layer 20, the space above the driving circuit layer 20 originally used for arranging the third light-emitting unit 33 can be used for arranging the support portion 50, thereby providing sufficient space to the support portion 50 without sacrificing the space for the pixel openings. The support portion 50 may be formed specifically by a photolithography process, for supporting the mask plate during the vaporization process to form the light-emitting layer, so as to avoid deformation of the mask plate.

The display panel 100 further includes a second encapsulation layer 70 and a cover plate 80; the second encapsulation layer 70 is arranged on a side of the second electrode layer 60 away from the substrate 10 and filled in the pixel openings for encapsulating the first light-emitting unit 31 and the second light-emitting unit 32; the second encapsulation layer 70 is leveled on the side away from the substrate 10; the second encapsulation layer 70 may specifically include an inorganic insulation layer and/or an organic insulating layer, which may be a single-layer structure or a multilayer structure, which may be set according to actual needs. The cover plate 80 is arranged covering a side of the second encapsulation layer 70 away from the substrate 10 for protecting the second encapsulation layer 70 and insulating the second encapsulation layer 70 from external water oxygen and dust. In the embodiments, a light emission side of the display panel 100 is the side where the substrate 10 is located, i.e., the light emission direction of the first light-emitting unit 31, the second light-emitting unit 32, and the third light-emitting unit 33 is toward the direction of the substrate 10. Of course, in other embodiments, the light emission side of the display panel 100 may be the side where the cover plate 80 is located, i.e., the light emission direction of the first light-emitting unit 31, the second light-emitting unit 32, and the third light-emitting units 33 are in the direction toward the cover plate 80.

The above is only some embodiments of the present disclosure, and is not intended to limit the scope of the present disclosure. Any equivalent structure or equivalent process transformation utilizing the contents of the specification of the present disclosure and the accompanying drawings, or directly or indirectly utilized in other related technical fields, are all reasonably included in the scope of the present disclosure.

What is claimed is:

1. A display panel, comprising:
a plurality of light-emitting units, arranged in a matrix and comprising a first light-emitting unit, a second light-emitting unit, and a third light-emitting unit of different colors; and
a plurality of subpixel driving circuits, in a one-to-one correspondence with and electrically connected to the plurality of light-emitting units for providing driving signals to the plurality of light-emitting units;
wherein each of the first light-emitting unit and the second light-emitting unit comprises an organic light-emitting diode (OLED) or a quantum dot light-emitting diode (QLED), and the third light-emitting unit comprises a micro light-emitting diode (Micro-LED);
the display panel further comprises a first power supply alignment and a second power supply alignment; the first power supply alignment is electrically connected to the third light-emitting unit for providing a first common voltage to the third light-emitting unit; the second power supply alignment is electrically connected to the first light-emitting unit and the second light-emitting unit for providing a second common voltage to the first light-emitting unit and the second light-emitting unit.

2. The display panel according to claim 1, wherein a plurality of the first light-emitting units, the second light-emitting units, and the third light-emitting units form a plurality of repeating units; each repeating unit comprises a corresponding set of the first light-emitting unit, the second light-emitting unit, and the third light-emitting unit; the plurality of repeating units comprise a first repeating unit and a second repeating unit;
in the first repeating unit, the first light-emitting unit is disposed in a first direction of the third light-emitting unit, and the second light-emitting unit is disposed in a direction opposite to the first direction of the third light-emitting unit;
in the second repeating unit, the second light-emitting unit is disposed in the first direction of the third light-emitting unit, and the first light-emitting unit is disposed in a direction opposite to the first direction of the third light-emitting unit;
wherein the plurality of repeating units are arranged in a matrix, with the first repeating units and the second repeating units being arranged alternately in a same row or a same column.

3. The display panel according to claim 2, further comprising:
scanning lines, each extending along a row direction; wherein each scanning line is electrically connected to each of the plurality of subpixel driving circuits that is disposed in a same row with the scanning line, for providing a scanning signal to the each of the plurality of subpixel driving circuits;
first data lines, each extending along a column direction; wherein each first data line is electrically connected to each of the plurality of subpixel driving circuits that is disposed in a same column with the first data line; wherein the each of the plurality of subpixel driving circuits is connected to the first light-emitting unit or the second light-emitting unit; and
a first drive module, electrically connected to the first data lines and configured to provide data signals to the first light-emitting unit and the second light-emitting unit.

4. The display panel according to claim 3, further comprising:
second data lines, each extending along the column direction; wherein each second data line is electrically connected to each of the plurality of subpixel driving circuits that is disposed in a same column with the second data line; wherein the each of the plurality of subpixel driving circuits is connected to the third light-emitting unit;
a second drive module, electrically connected to the second data lines and configured to provide data signals to the third light-emitting unit; and
third power supply alignments, each extending along the column direction; wherein each third power supply alignment is electrically connected to each of the plurality of subpixel driving circuits that is disposed in a same column with the third power supply alignment, for providing a power supply voltage to the each of the plurality of subpixel driving circuits; the third power supply alignments are shorted through a third power supply bus disposed at an edge of the display panel.

5. The display panel according to claim 4, wherein each adjacent two columns of the subpixel driving circuits electrically connected to the first light emitting units are electrically connected to a corresponding first data line; and/or, each adjacent two columns of the subpixel driving circuits electrically connected to the second light emitting units are electrically connected to a corresponding first data line.

6. The display panel according to claim 1, wherein each subpixel driving circuit comprises a switching unit, a driving unit, and a storage unit; a control end of the switching unit is connected to a scanning line, a first end of the switching unit is connected to a data line, and a second end of the switching unit is connected to a first node; a control end of the driving unit is connected to the first node, a first end of the driving unit is connected to a second node, a second end of the driving unit is connected to an anode of a corresponding light-emitting unit, and the second node is connected to a third power supply signal line; a first end of the storage unit is connected to the first node, and a second end of the storage unit is connected to the second node; a cathode of the corresponding light-emitting unit is connected to a first power supply signal line or a second power supply signal line.

7. The display panel according to claim 6, wherein the switching unit comprises a switching transistor, the driving unit comprises a driving transistor, and the storage unit comprises a storage capacitor; a gate of the switching transistor is connected to the scanning line, a first end of the switching transistor is connected to the data line, and a second end of the switching transistor is connected to the first node; a gate of the driving transistor is connected to the first node, a first end of the driving transistor is connected to the second node, and a second end of the driving transistor is connected to the light-emitting element; a first end and a second end of the storage capacitor are connected to the first node and the second node, respectively.

8. A display panel, comprising:
a substrate;
a driving circuit layer, arranged on a side of the substrate and comprising a plurality of subpixel driving circuits; and
a plurality of light-emitting units, arranged in a matrix and in a one-to-one correspondence with and electrically connected to the plurality of subpixel driving circuits; wherein the plurality of light-emitting units comprises a first light-emitting unit, a second light-emitting unit, and a third light-emitting unit of different colors;
wherein each of the first light-emitting unit and the second light-emitting unit comprises an organic light-emitting diode (OLED) or a quantum dot light-emitting diode (QLED), and the third light-emitting unit comprises a micro light-emitting diode (Micro-LED);
the driving circuit layer further comprises a plurality of first power supply alignments, each extending along a column direction; wherein the third light-emitting unit comprises a second electrode, and the second electrodes of the third light-emitting units in a same column or a same row are electrically connected to a corresponding first power supply alignment;
a fourth electrode of the first light-emitting unit and a fourth electrode of the second light-emitting unit are electrically connected to each other to form a second power supply alignment for providing a second common voltage to the first light-emitting unit and the second light-emitting unit.

9. The display panel according to claim 8, further comprising: a buffer layer; wherein the buffer layer is disposed between the substrate and the driving circuit layer, and a plurality of accommodation slots are defined on a side of the buffer layer away from the substrate; each accommodation slot is configured to arrange a corresponding third light-emitting unit; a first electrode and the second electrode of the corresponding third light-emitting unit are oriented toward a slot opening of the accommodation slot.

10. The display panel according to claim 9, further comprising: a first encapsulation layer; wherein the first encapsulation layer is arranged between the buffer layer and the driving circuit layer for encapsulating the third light-emitting unit; the first encapsulation layer defines openings for exposing the first electrode and the second electrode;
the first electrode is electrically connected to a corresponding subpixel driving circuit of the driving circuit layer, and the second electrode is electrically connected to a corresponding first power supply alignment.

11. The display panel according to claim 9, further comprising: a first electrode layer;
wherein the first electrode layer is arranged on a side of the driving circuit layer away from the substrate, and the first electrode layer comprises a plurality of third electrodes; the plurality of third electrodes are misaligned with the third light-emitting units in a direction perpendicular to the substrate; each third electrode is electrically connected to a corresponding subpixel driving circuit.

12. The display panel according to claim 11, further comprising: a light-emitting layer;
wherein the light-emitting layer is arranged on a side of the third electrode away from the substrate, and the light-emitting layer comprises a first light-emitting layer and a second light-emitting layer of different colors.

13. The display panel according to claim 12, further comprising: a second electrode layer;
wherein the second electrode layer is arranged on a side of the light-emitting layer away from the substrate, and the second electrode layer comprises a plurality of fourth electrodes electrically connected to each other; wherein the first light-emitting layer, a corresponding third electrode, and a corresponding fourth electrode form the first light-emitting unit; the second light-emitting layer, a corresponding third electrode, and a corresponding fourth electrode form the second light-emitting unit.

14. The display panel according to claim 13, further comprising a pixel defining layer;
wherein the pixel defining layer is arranged on a side of the first electrode layer away from the substrate, and the pixel defining layer defines a plurality of pixel openings in a one-to-one correspondence with the plurality of third electrodes for exposing the plurality of third electrodes.

15. The display panel according to claim 14, further comprising a support portion;
wherein the support portion is disposed on a side of the pixel defining layer away from the substrate, and a positive projection of the support portion on the substrate is overlapped with a positive projection of a corresponding third light-emitting unit on the substrate.

16. The display panel according to claim 14, further comprising a second encapsulation layer;
wherein the second encapsulation layer is arranged on a side of the second electrode layer away from the substrate and filled in the pixel openings for encapsulating the first light-emitting unit and the second light-emitting unit.

17. The display panel according to claim 16, further comprising a cover plate;
wherein the cover plate is arranged covering a side of the second encapsulation layer away from the substrate.

18. The display panel according to claim 9, wherein an epitaxial layer in arranged in the third light-emitting unit oriented toward the substrate.

19. The display panel according to claim 8, wherein the driving circuit layer comprises a first metal layer, a first insulating layer, an active layer, a second insulating layer, a second metal layer, a third insulating layer, and a third metal layer disposed in a sequential cascade;
wherein the first power supply alignment is disposed in the first metal layer; the first metal layer further comprises a plurality of patterned light shielding layers;
a positive projection of the active layer on the substrate falls within a positive projection of the light-shielding layer on the substrate;
the second metal layer comprises gate and scanning lines; each scanning line extends along a row direction of the matrix, and the gates in a same row are electrically connected to a corresponding scanning line;
the third metal layer comprises a source, a drain, a third electrode, a data line, a third power supply alignment, and the third electrode, the third electrode being electrically connected to the source; the data line is arranged between corresponding adjacent two of the plurality of light-emitting units, extends in a column direction of the matrix, and is electrically connected to a corresponding subpixel driving circuit; the third power supply alignment is arranged between corresponding adjacent two of the plurality of light-emitting units and extends in the column direction of the matrix; the third power supply alignment is spaced apart from the data lines, and the third power supply alignment is electrically connected to the drain for providing a power supply voltage to a corresponding light-emitting unit.

20. The display panel according to claim 8, wherein a plurality of the first light-emitting units, the second light-emitting units, and the third light-emitting units form a plurality of repeating units; each repeating unit comprises a corresponding set of the first light-emitting unit, the second light-emitting unit, and the third light-emitting unit; the plurality of repeating units comprise a first repeating unit and a second repeating unit;
in the first repeating unit, the first light-emitting unit is disposed in a first direction of the third light-emitting unit, and the second light-emitting unit is disposed in a direction opposite to the first direction of the third light-emitting unit; in the second repeating unit, the second light-emitting unit is disposed in the first direction of the third light-emitting unit, and the first light-emitting unit is disposed in a direction opposite to the first direction of the third light-emitting unit; wherein the plurality of repeating units are arranged in a matrix, with the first repeating units and the second repeating units being arranged alternately in a same row or a same column;
wherein in a set of the first repeating unit and the second repeating unit being adjacent to each other, adjacent two of the plurality of first light-emitting units share a same vaporization opening on a mask plate, and/or adjacent two of the plurality of second light-emitting units share a same vaporization opening on the mask plate; adjacent two columns of the plurality of subpixel driving circuits connected to corresponding first light-emitting units and corresponding second light-emitting units are electrically connected to a same data line.
